(19) United States
(12) Patent Application Publication
(10) Pub. No.: US 2008/0171440 A1
(43) Pub. Date: Jul. 17, 2008

(54) Pre-polishing treatment solution for interconnect substrate, polishing method, and method and apparatus for manufacturing interconnect substrate

(76) Inventors: Akira Kodera, Kanagawa-ken (JP); Takayuki Saito, Kanagawa-ken (JP); Yasushi Toma, Kanagawa-ken (JP); Tsukuru Suzuki, Kanagawa-ken (JP); Itsuki Kobata, Tokyo (JP)

Correspondence Address: WENDEROTH, LIND & PONACK, L.L.P., 2033 K STREET N. W., SUITE 800, WASHINGTON, DC, 20006-1021, US

(21) Appl. No.: 12/007,786

(22) Filed: Jan. 15, 2008

(30) Foreign Application Priority Data
Jan. 16, 2007 (JP) 2007-006489

(51) Int. Cl. H01L 21/304; C23F 11/14; B23H 3/00

(52) U.S. Cl. 438/692; 252/394; 156/345.12; 205/661; 257/E21.304

(57) ABSTRACT

A pre-polishing treatment solution has a prominent corrosion inhibiting effect, and can be used in pre-polishing treatments for interconnect substrates. The pre-polishing treatment solution comprises a corrosion inhibitor dissolved in an organic solvent.

### BACKGROUND OF THE INVENTION

1. Field of the Invention

The present invention relates to a polishing method for flattening an irregular surface, associated with an interconnect structure, of a substrate, a pretreatment solution containing a corrosion inhibitor for use in the polishing method, and a method for manufacturing an interconnect substrate. The present invention is especially useful for polishing and manufacturing of an interconnect substrate having a multi-level interconnect structure, such as a semiconductor device or a liquid crystal display.

2. Description of the Related Art

Techniques for flattening an irregular surface, which is associated with a multi-level interconnect structure, of a semiconductor device include: CMP (chemical mechanical polishing) which is a chemical mechanical polishing technique involving contact between a polishing pad and a workpiece; chemical polishing (etching) which involves immersing a workpiece in a chemical to flatten a polishing surface through a chemical reaction; electrolytic polishing which involves applying a voltage between a metallic workpiece as an anode and an electrode tool as a cathode in an electrolytic liquid to electrolytically dissolve (oxidize) a surface of the workpiece; electrolytic processing that utilizes electrolytic dissolution by high-current density application in an aqueous neutral salt solution; and composite electrolytic polishing which processes a workpiece by supplying a pressurized electrolytic liquid and applying a pressure at not more than 40 kPa while applying an electric current at a current density on the order of 0.1 to 1 A/cm². For the formation of interconnects in a semiconductor device is employed a damascene process which involves filling an interconnect metal (such as Cu, Al, Ag or Au) into interconnect recesses, such as trenches and via holes, provided in an insulating film, followed by removal of an extra interconnect metal film. More specifically, interconnect recesses are formed in an insulating film (interlevel dielectric film) of, for example, SiO₂, SiOF, SiOC or a low-k (low-dielectric constant) material, formed on a substrate, and a barrier film of, for example, titanium, tantalum, tungsten, ruthenium, and/or an alloy thereof, is formed on a surface of the insulating film, including the surfaces of the interconnect recesses. An interconnect metal film of aluminum, copper, silver, gold, or an alloy thereof is then formed on a surface of the barrier film, thereby filling the interconnect recesses with the interconnect metal. Thereafter, an extra interconnect metal film and an extra barrier film, lying outside the interconnect recesses, are removed. When processing a mechanically weak material, such as a low-k material, there is a fear of failure of the material, e.g., due to buckling, and therefore application of a high load to the substrate must be avoided. CMP or composite electrolytic polishing, which can perform processing of the substrate at a low pressure (about 103 hPa), is therefore generally employed. Composite electrolytic polishing is a polishing method which simultaneously performs chemical modification or chemical dissolution of a surface of a metal film and scrub removal of the surface of the metal film by mechanical contact between the surface of the metal film and a contact member. Electrolytic polishing has also been proposed which carries out removal processing of a metal film not by mechanical polishing, but by causing a chemical dissolution reaction at the surface of the metal film.

In such composite electrolytic polishing, CMP (chemical mechanical polishing) or electrolytic polishing, a corrosion inhibitor (having the function of forming a reaction layer on a surface of an interconnect metal to inhibit dissolution/corrosion of the metal) to prevent over-polishing in recessed portions is often added to a polishing liquid, such as a composite electrolytic polishing liquid, a CMP slurry or an electrolytic polishing liquid, in order to flatten surface irregularities of a polishing object (mainly an interconnect metal such as tungsten, copper or a copper alloy). Since these common polishing liquids are aqueous liquids comprising water as a solvent, it is necessary to use a water-soluble corrosion inhibitor. A corrosion inhibitor has, in its molecular structure, a hydrophobic group, such as an alkyl group or a phenyl group, which, when attached to a substrate surface, inhibits wetting of the substrate surface by an aqueous liquid and also inhibits penetration of a molecule, capable of dissolving the substrate surface, into the substrate, thus inhibiting dissolution/corrosion of the substrate surface (interconnect metal). However, a corrosion inhibitor having such a hydrophobic group at a higher proportion in a molecule has a lower water solubility. Thus, it has not been possible to use a corrosion inhibitor which is insoluble or hardly soluble in water, although it has a very high corrosion inhibiting effect.

On the other hand, an organic solvent, if used in a polishing processing, can explode upon heating, and can also dissolve a resin material, such as a polishing pad, used in the polishing. Therefore, an organic solvent has not been generally used in polishing (Japanese Patent Laid-Open Publication Nos. 2001-77117 and 2003-77921).

### SUMMARY OF THE INVENTION

It is an object of the present invention to provide a pre-polishing treatment solution having a prominent corrosion inhibiting effect, which can be used in pre-polishing treatments for various types of interconnect substrates, especially substrates having multi-level interconnects, in the manufacturing of semiconductor devices or flat-panel displays) and to provide a polishing method that uses the pretreatment solution.

It is another object of the present invention to provide an interconnect substrate manufacturing method that uses the pre-polishing treatment solution.

In order to achieve the above objects, the present invention provides a pre-polishing treatment solution for an interconnect substrate having an interconnect metal layer, comprising a corrosion inhibitor dissolved in an organic solvent. The term “interconnect substrate” herein refers to a substrate having an interconnect metal layer(s).

Examples of corrosion inhibitors usable in the present invention include: 2,3-benzopyrrole; imidazole derivatives such as 2-ethyl imidazole, 4-methyl imidazole, 4-methyl-5-hydroxymethyl imidazole, 1-butyl-5-methyl imidazole, 1-phenyl-4-methyl imidazole, 1-(p-tolyl)-4-methyl imidazole, benzimidazole, 2-methyl benzimidazole, 5,6-dimethyl benzimidazole, 2-mercapto benzimidazole and 2-amino benzimidazole; triazole derivatives such as benzotriazole, 5-methyl-1H-benzotriazole, 1-hydroxy benzotriazole, 4-hydroxy benzotriazole, 5-chloro benzotriazole, benzotriazole-5-carboxylic acid, 5-nitro benzotriazole, 1,2,4-triazole, 3-amino-1,2,4-triazole, 3-amino-5-methyl-4H-1,2,4-triazole and 3-phenyl-1,2,4-triazole-5-thione; 2-amino-4,6-dimethyl pyrimidine; 5-amino-1H-tetrazole; benzothiazole derivatives such as 2-mercapto benzothiazole, sodium 2-mercapto benzothiazole and 2-methyl benzothiazole; benzothiazolylthio derivatives such as (2-benzothiazolylthio)acetic acid and 3-(2-benzothiazolylthio)propionic acid; 2-mercapto-2-thiazoline; thiadiazole derivatives such as 2-5-dimercapto-1,3,4-thiadiazole, 5-methyl-1,3,4-thiadiazole-2-thiol and 5-amino-1,3,4-thiadiazole-2-thiol; 2-mercapto benzoxazole; pyridine; phenazine; acridine; 1-hydroxypyridine-2-thione; 2-aminopyridine; 2-aminopyrimidine; trithiocyanuric acid; triazine derivatives such as 2-dibutylamino-4,6-dimercapto-s-triazine and 2-anilino-4,6-dimercapto-s-triazine; nicotinic acid; quinolinol derivatives such as 8-quinolinol, 2-methyl-8-quinolinol and 2-quinolinecarboxylic acid; adenine; 6-thioguanine; uric acid; caffeine; amines such as methyl amine, dimethyl amine, ethyl amine, diethyl amine, butyl amine, dimethylbutyl amine, hexadecyl amine, dimethyhexadecyl amine, cyclohexyl amine, cyclohexyl dimethyl amine, octyl amine, dimethyloctyl amine, dodecyl amine, octadecyl amine, dimethyldodecyl amine, phenyldodecyl amine, tolyldodecyl amine, cyclohexyldodecyl amine, benzyldodecyl amine, N-methyl-N-cetyl-2-ethanol amine, N-methyl-N-cetyl-3-propanol amine, N,N-dimethyl-cetyl amine, N-methyl-N-propylcetyl amine, p-phenylene diamine, ethylene diamine, N,N,N′,N′-dimethylethylene diamine, N,N,N′,N′-tetramethylethylene diamine, diethylene triamine, diethylcetyl amine, diethylcetyl amine hydrochloride, monoethanol amine, diethanol amine and triethanol amine; alkanethiols such as 11-mercapto-1-undecanol; ω-mercapto carboxylic acids; urea derivatives such as thiourea, phenyl urea, 1-α-pyridylamino-3-benzoyl-2-thiourea, 1-α-pyridylamino-3-phenyl-2-thiourea and 1-α-pyridylamino-3-phenyl-2-urea; phenacetin; thiosemicarbazide; dithiooxamide; thiocarbamic acid derivatives such as potassium N,N-dimethylthiocarbamate monohydrate and sodium N,N-diethyldithiocarbamate trihydrate; salicylic acid derivatives such as salicylic acid, thiosalicylic acid, salicylaldehyde, salicylaldoxime and a schiff base formed from 3-methoxy salicylaldehyde and o-phenylene diamine; cupferron; cupron; 1-nitroso-2-naphthol; thionalide; catechol; arylmethylene cyanothioacetamide derivatives such as 4-methoxyphenylmethylene cyanothioacetamide, 4-methylphenylmethylene cyanothioacetamide, 4-chlorophenylmethylene cyanothioacetamide, 4-bromophenylmethylene cyanothioacetamide and 4-nitrophenylmethylene cyanothioacetamide; caproic acid amide derivatives such as caproic acid amide and dimethylcaproic acid amide; hexamethylene tetramine; aniline derivatives such as p-nitroaniline and p-chloroaniline; p-aminophenol; p-aminobenzamide; p-aminoacetoanilide; acridine derivatives such as acridine and 9-aminoacridine; ethylene glycol; quinolinium derivatives such as 2-(2-hydroxystyryl)quinolinium-1-ethyl iodide and 4-(2-hydroxystyryl) quinolinium-1-ethyl iodide cyanine dye; 2-(o-hydroxystyryl)pyridinium-1-ethyl iodide cyanine dye; nitrile derivatives such as acrylonitrile, phenylacetonitrile, acetonitrile and trichloroacetonitrile; benzoylbenzaldehyde hydrazone derivatives; pyridylhydrazone derivatives such as 2-furancarboxaldehyde-(2′-pyridylhydrazone), 2-pyrrolecarboxaldehyde-(2′-pyridylhydrazone) and 2-thiophenecarboxaldehyde-(2′-pyridylhydrazone); anisidines such as p-anisidine and o-anisidine; toluidines such as p-toluidine and o-toluidine; cetylpyridinium derivatives such as cetylpyridinium chloride and cetylpyridinium bromide; 2,3,5-triphenyl tetrazonium chloride; resorcinol; cresol; salicylaldehyde; hydroxybenzophenoxime derivatives; L-hydroxy-5-nonyl acetone phenonoxime; citric acid; tartaric acid; malonic acid; oxalic acid; maleic acid; polyacrylic acid or its salts; polymaleic acid or its salts; polymalic acid; polyvinyl pyrrolidone; polyamide; polymethacrylic acid or its salts; polyethylene glycol; polyacrylamide derivatives such as polyisopropyl acrylamide, polydimethyl acrylamide and polymethacrylamide; polymethoxy ethylene; polyvinyl alcohol; polypyrrol; polyethylene imine; polyoxyethylene alkyl ether; polyalkylene polyamine; polyallylamine; polystyrene sulfonic acid salts; polyethyleneimine; acrylamide acrylic acid copolymer; celluloses such as hydroxyethyl cellulose and carboxymethyl cellulose; acetic acid derivatives such as monochloroacetic acid, dichloroacetic acid, trichloroacetic acid, bromoacetic acid and iodoacetic acid; xanthan hydrogen; 3-amino-1,2,4-dithioazolidinethion-5; isoperthiocyanic acid; lipoic acid; condensed phosphates such as lipoic acid, linear condensed phosphates and cyclic condensed phosphates; dodecylpyrrole; anionic surfactants such as lauryl phosphate, lauryl ether phosphate, polyoxyethylene alkyl ether phosphate, polyoxyethylene phenyl ether phosphate, polyoxyethylene alkylphenyl ether phosphate, alkali metal (Na, K, etc.) salts or ammonium salts of these phosphate esters, lauroyl sarcosine and oleoyl sarcosine; and nonionic surfactants such as polyoxyethylene-polyoxypropylene-ethylenediamine block copolymer, oleic diethanolamide, linoleic diethanolamide, stearic monoethanolamide, stearic diethanolamide, myristic monoethanolamide, myristic diethanolamide, lauric diethanolamide., coconut fatty acid diethanolamide, palm kernel fatty acid diethanolamide, coconut fatty acid monoethanolamide and lauric isopropanolamide.

Particularly preferable corrosion inhibitors are 2-ethyl imidazole, benzimidazole, benzotriazole, 5-methyl-1H-benzotriazole, 1,2,4-triazole, 3-amino-5-methyl-4H-1,2,4-triazole, 2-mercapto benzothiazole, nicotinic acid, adenine, 6-thioguanine, uric acid, caffeine, 8-quinolinol, 2-methyl-8-quinolinol, thiourea, phenyl urea, salicylic acid, thiosalicylic acid, salicylaldoxime, lauryl phosphate, lauryl ether phosphate, polyoxyethylene alkyl ether phosphate, polyoxyethylene phenyl ether phosphate, polyoxyethylene alkylphenyl ether phosphate, lauroyl sarcosine, oleoyl sarcosine, oleic diethanolamide, linoleic diethanolamide, stearic monoethanolamide, stearic diethanolamide, myristic monoethanolamide, myristic diethanolamide, lauric diethanolamide, coconut fatty acid diethanolamide, palm kernel fatty acid diethanolamide, coconut fatty acid monoethanolamide and lauric isopropanolamide.

While the above corrosion inhibitors having a hydrophobic group are hardly soluble in water, they have relatively high solubilities in organic solvents. For example, the solubility of benzotriazole (BTA) in water is about 2% (20° C.), whereas the solubility in methanol is 56.3%, the solubility in ethanol is 47.5%, the solubility in acetone is 47.5%, the solubility in ethylene glycol is 40.6%, the solubility in diethylene glycol is 52.2% and the solubility in ethanolamine is 28.0%.

Methanol, ethanol, propanol, butanol, acetone, hexane, tetrahydrofuran, etc. can be preferably used as an organic solvent for the pretreatment solution of the present invention. The use of an organic solvent having a low boiling point, such as ethanol, is preferred because the solvent can be evaporated more quickly from a substrate after attaching a corrosion inhibitor to the substrate.

A corrosion inhibitor in the pretreatment solution of the present invention is preferably contained in an amount of 0.01 to 50 wt %, more preferably 0.1 to 20 wt %, most preferably 1 to 5 wt % of the amount of the organic solvent used. The use of a corrosion inhibitor in a high concentration is advantageous if the amount of the corrosion inhibitor that adheres to a metal substrate is proportional to the concentration of the corrosion inhibitor in the pretreatment solution.

Some corrosion inhibitors (for example, imidazole derivatives and triazole derivatives) preferentially react and combine with copper oxide. It is therefore preferred to pre-oxidize metallic copper when such a corrosion inhibitor is used and, to this end, the pretreatment solution should preferably contain an oxidizing agent. Examples of usable oxidizing agents include organic peroxides, such as ozone water, hydrogen peroxide, peracetic acid, perbenzoic acid and tert-butylhydroperoxide; permanganic acid compounds, such as potassium permanganate; bichromic acid compounds, such as potassium bicromate; halogen acid compounds, such as potassium iodate; nitric acid compounds, such as nitric acid and iron nitrate; perhalogen acid compounds, such as perchloric acid; transition metal salts, such as potassium ferricyanide; persulfates, such as ammonium persulfate; and heteropolyacid salts.

The pretreatment solution of the present invention can be advantageously used in chemical mechanical polishing (CMP), electrolytic polishing or composite electrolytic polishing, especially in a pre-polishing treatment in the manufacturing of semiconductor devices or flat-panel displays.

The present invention also provides a method for polishing an interconnect substrate, comprising: the step of providing an interconnect substrate having an interconnect metal layer on a barrier metal layer; the pretreatment solution application step of applying the above-described pretreatment solution to the interconnect substrate; the first polishing step of flattening the interconnect metal layer; and the second polishing step of removing the barrier metal layer exposed on the surface of the interconnect substrate.

The pretreatment solution application step is preferably carried out as pretreatment before the first polishing step or as pretreatment before the second polishing step, and is more preferably carried out as pretreatment before the first polishing step and as pretreatment before the second polishing step. In the first polishing step and/or the second polishing step is preferably carried out polishing selected from chemical mechanical polishing (CMP), electrolytic polishing and composite electrolytic polishing.

An aspect of the method for manufacturing an interconnect substrate according to the present invention comprises the steps of: depositing an interconnect metal on a barrier metal layer covering a substrate surface having interconnect recesses, thereby forming an interconnect substrate; applying the above-described pretreatment solution to a surface of the interconnect metal layer; polishing the interconnect metal layer; and then polishing away the exposed barrier metal layer and flattening the surface of the interconnect substrate.

Another aspect of the method for manufacturing an interconnect substrate according to the present invention comprises the steps of: depositing an interconnect metal on a barrier metal layer covering a substrate surface having interconnect recesses, thereby forming an interconnect substrate; polishing the interconnect substrate and exposing a surface of the interconnect metal; applying the above-described pretreatment solution to the surface of the interconnect metal; and then polishing the interconnect substrate to remove the exposed barrier metal layer.

Yet another aspect of the method for manufacturing an interconnect substrate according to the present invention comprises the steps of: depositing an interconnect metal on a barrier metal layer covering a substrate surface having interconnect recesses, thereby forming an interconnect substrate; applying the above-described pretreatment solution to a surface of the interconnect metal; polishing the interconnect substrate and exposing the surface of the interconnect metal; applying the above-described pretreatment solution to the surface of the interconnect metal; and then polishing the interconnect substrate to remove the exposed barrier metal layer.

An interconnect substrate generally has surface irregularities immediately after a metal is filled into interconnect recesses, formed in the substrate surface, by a wet method such as plating or by a dry method such as sputtering or CVD (chemical vapor deposition). When processing the interconnect substrate by composite electrolytic polishing or CMP, a corrosion inhibitor contained in the processing liquid adheres to an entire surface of interconnect metal layer. During the composite electrolytic polishing or CMP, the interconnect substrate is polished while a mechanical pressure is applied by a polishing pad preferentially to raised portions of the substrate surface, whereby the corrosion inhibitor is peeled off from the raised portions and the interconnect metal layer, covered with the corrosion inhibitor, becomes exposed. The exposed interconnect metal layer is dissolved by contact with a metal dissolving agent in the processing liquid. On the other hand, the corrosion inhibitor adhering to recessed portions of the interconnect substrate, because of less polishing pressure applied than that applied to raised portions, is little peeled off. Thus, the interconnect metal layer is little exposed in the recessed portions, and therefore is hardly attacked by the dissolving agent and dissolved. As the processing progresses, however, the surface irregularities of the interconnect substrate gradually decreases, and a sufficient polishing pressure comes to be applied to the former recessed portions, whereby the corrosion inhibitor on those portions is peeled off and the underlying interconnect metal layer becomes exposed and dissolved. Flattening of the interconnect substrate is effected in this manner. In an advanced stage of polishing when flattening of the substrate surface progresses after the barrier metal layer, underlying the interconnect metal layer, has become exposed, processing must be carried out with only the metal in the interconnect recesses left. Polishing must then be controlled so as not to excessively polish the metal in the interconnect recesses.

In the polishing method of the present invention, prior to polishing, a corrosion inhibitor is attached to a surface of an interconnect substrate, having an interconnect metal embedded in the surface, by using the pretreatment solution of the present invention. Usable methods for the attachment of the corrosion inhibitor to the substrate surface include an immersion method in which the interconnect substrate is immersed in the pretreatment solution, a spin-coating method in which while rotating the interconnect substrate, an appropriate amount of the pretreatment solution is dropped from above the center of the interconnect substrate, a spray coating method in which the pretreatment solution is sprayed from above the interconnect substrate while moving the interconnect substrate horizontally in one direction, a roll printing method in which the pretreatment solution is transfer-printed on the interconnect substrate by means of a printing roll, etc. The spin-coating method, the spray coating method and the roll printing method are preferred because of no contamination of the back surface of the interconnect substrate. In the case of roll printing method, it is desirable that the roll easily follow the surface irregularities of the interconnect substrate. It is therefore preferred to use, for example, a silicone resin, an organic solvent-resistant rubber material such as an organic solvent-resistant polyurethane resin, or a thermoplastic elastomer material as a material for the roll. The pretreatment solution of the present invention, because of the inclusion of an organic solvent, does not require provision of a step for the removal of the pretreatment solution. Thus, since the organic solvent vaporizes immediately after it adheres to the surface of the interconnect substrate, a corrosion inhibiting protective film can be formed on the substrate surface easily in a short time. The spin-coating method and the spray coating method are therefore particularly preferred as a pretreatment method for applying the pretreatment solution of the present invention to the surface of the interconnect substrate. The pretreatment step of the present invention is carried out at a different place from polishing. Accordingly, the use of an organic solvent does not have an adverse effect on a polishing member, such as a polishing pad, nor on a polishing process.

### BRIEF DESCRIPTION OF THE DRAWINGS

FIG. 1 is a diagram illustrating a composite electrolytic polishing process using a pretreatment solution of the present invention; and

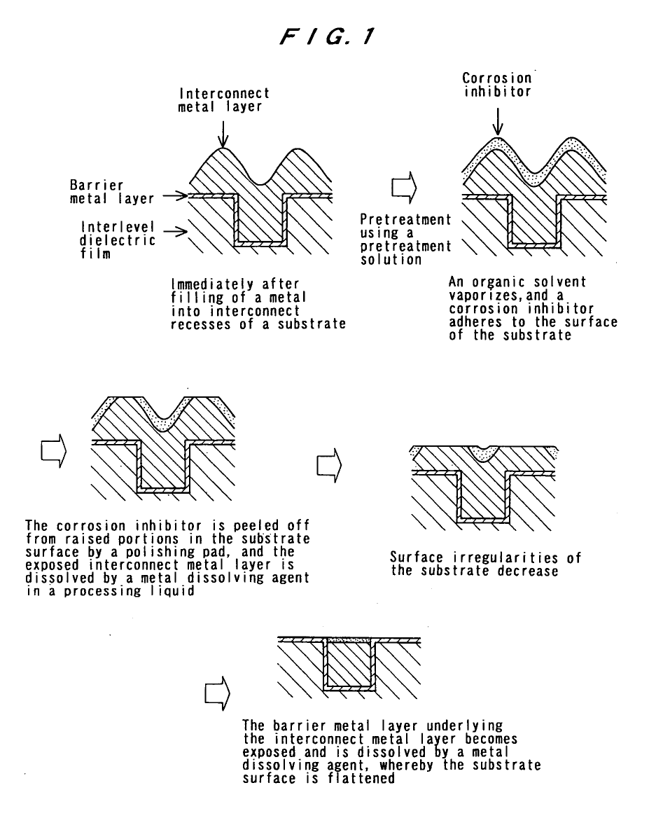

FIG. 2 is a layout plan view of a polishing apparatus for carrying out the polishing method of the present invention.

### DETAILED DESCRIPTION OF THE PREFERRED EMBODIMENTS

In a first embodiment of the present invention, an interconnect metal (semiconductor interconnect metal, such as copper, a copper alloy or tungsten) is filled into interconnect recesses of a substrate by a wet method, such as plating, or by a dry method, such as CVD to form an interconnect substrate. Thereafter, a pretreatment solution is applied to the interconnect substrate by immersing the interconnect substrate in the pretreatment solution, or by using a spin coating method, a spray coating method or a roll coating method, thereby forming a corrosion inhibiting protective film of a corrosion inhibitor on a surface of the interconnect substrate including the interconnect metal (pretreatment). Next, the surface of the interconnect substrate is polished until a thickness of the interconnect metal layer, such as copper, reaches a predetermined value (first polishing step). Next, the interconnect metal layer remaining on the surface of the interconnect substrate and/or an exposed barrier metal layer is removed by polishing (second polishing step).

In a second embodiment of the present invention, an interconnect metal (semiconductor interconnect metal, such as copper, a copper alloy or tungsten) is filled into interconnect recesses of a substrate by a wet method, such as plating, or by a dry method, such as CVD to form an interconnect substrate. Thereafter, a pretreatment solution is applied to the interconnect substrate by immersing the interconnect substrate in the pretreatment solution, or by using a spin coating method, a spray coating method or a roll coating method, thereby forming a corrosion inhibiting protective film of a corrosion inhibitor on a surface of the interconnect substrate including the interconnect metal layer (pretreatment). Next, the interconnect metal (such as copper) covering those portions of the substrate surface other than the interconnect recesses is polished and flattened (first polishing step). Next, the interconnect metal and/or a barrier metal layer exposed on the surface of the interconnect substrate is removed by polishing (second polishing step).

In a third embodiment of the present invention, an interconnect metal (semiconductor interconnect metal, such as copper, a copper alloy or tungsten) is filled into interconnect recesses of a substrate by a wet method, such as plating, or by a dry method, such as CVD to form an interconnect substrate. Thereafter, a surface of the interconnect substrate is polished until the interconnect metal (such as copper), covering those portions of the substrate surface other than the interconnect recesses, is polished to a predetermined thickness or is completely removed (first polishing step). Next, a pretreatment solution is applied to the interconnect substrate by immersing the interconnect substrate in the pretreatment solution, or by using a spin coating method, a spray coating method or a roll coating method, thereby forming a corrosion inhibiting protective film of a corrosion inhibitor on the surface of the interconnect substrate including the interconnect metal layer (pretreatment). Next, the interconnect metal layer remaining on the surface of the interconnect substrate and/or an exposed barrier metal layer is removed by polishing (second polishing step). In the second polishing step of this embodiment, the pretreatment solution comes into contact with both the interconnect metal layer and the barrier metal layer. The pretreatment solution selectively adheres to the interconnect metal, such as copper, and therefore a corrosion inhibiting protective film is not formed on the barrier metal layer or, if formed, the protective film will not have a sufficient corrosion inhibiting effect.

In a fourth embodiment of the present invention, an interconnect metal (semiconductor interconnect metal, such as copper, a copper alloy or tungsten) is filled into interconnect recesses of a substrate by a wet method, such as plating, or by a dry method, such as CVD to form an interconnect substrate. Thereafter, a pretreatment solution is applied to the interconnect substrate by immersing the interconnect substrate in the pretreatment solution, or by using a spin coating method, a spray coating method or a roll coating method, thereby forming a corrosion inhibiting protective film of a corrosion inhibitor on the surface of the interconnect substrate including the interconnect metal layer (pretreatment). Next, a surface of the interconnect substrate is polished until a thickness of the interconnect metal, such as copper, reaches a predetermined value (first polishing step). Next, a pretreatment solution is applied to the interconnect substrate by immersing the interconnect substrate in the pretreatment solution, or by using a spin coating method, a spray coating method or a roll coating method, thereby forming a corrosion inhibiting protective film of a corrosion inhibitor on the surface of the interconnect substrate including the interconnect metal layer (pretreatment) Next, the interconnect metal layer remaining on the surface of the interconnect substrate and an exposed barrier metal layer are removed by polishing (second polishing step). In the second polishing step of this embodiment, the pretreatment solution comes into contact with both the interconnect metal layer and the barrier metal layer. The pretreatment solution selectively adheres to the interconnect metal layer, such as copper, and therefore a corrosion inhibiting protective film is not formed on the barrier metal layer or, if formed, the protective film will not have a sufficient corrosion inhibiting effect.

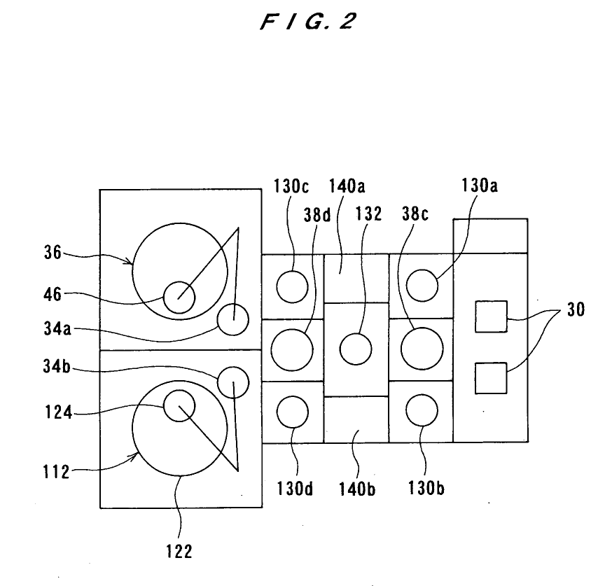

The polishing method of the present invention can be carried out using a polishing apparatus shown in FIG. 2. The polishing apparatus shown in FIG. 2 includes a pair of loading/unloading sections 30 as a carry-in/carry-out section for carrying in/carrying out a cassette housing interconnect substrates, pushers 34a, 34b, and an electrolytic processing apparatus 36 and a CMP apparatus 112 both as a polishing section, and also includes two first cleaning apparatuses 130a, 130b and two second cleaning apparatuses 130c, 130d. Pretreatment units 140a, 140b are provided between the first cleaning apparatuses 130a, 130b and the second cleaning apparatuses 130c, 130d. Further, a substrate stage 132 having a substrate-reversing function is disposed between the first cleaning apparatuses 130a, 130b and the second cleaning apparatuses 130c, 130d. At a position surrounded by the loading/unloading sections 30, the first cleaning apparatuses 130a, 130b and the substrate stage 132 is disposed a first transport robot 38c as a transport device for transferring an interconnect substrate between them. Further, at a position surrounded by the substrate stage 132, the second cleaning apparatuses 130c, 130d and the pushers 34a, 34b is disposed a second transport robot 38d as a transport device for transferring the interconnect substrate between them.

A process for polishing an interconnect substrate by this polishing apparatus will now be described. An interconnect substrate placed in the loading/unloading section 30 is transported by the first transport robot 38c to the substrate stage 132, and is then transported by the first transport robot 38c to the pretreatment unit 140a. In the pretreatment unit 140a, a pretreatment solution is applied to the interconnect substrate. Thereafter, the interconnect substrate is transported by the second transport robot 38d to the electrolytic processing apparatus 36, where the substrate is subjected to the first polishing step. Next, the interconnect substrate is transported by the second transport robot 38d to the CMP apparatus 112, where the substrate is subjected to the second polishing step to carry out finish polishing. The interconnect substrate after polishing is transported by the second transport robot 38d to the second cleaning apparatus 130d, where the substrate is cleaned. Thereafter, the interconnect substrate is transported by the second transport robot 38d to the substrate stage 132, where the substrate is reversed as necessary. The interconnect substrate is then transported by the first transport robot 38c to the first cleaning apparatus 130b, where the substrate is finish, cleaned and dried. Thereafter, the interconnect substrate is returned by the first transport robot 38c to the loading/unloading section 30.

In the polishing apparatus shown in FIG. 2, instead of the combination of the electrolytic processing apparatus and the CMP apparatus, it is also possible to provide either a pair of the electrolytic processing apparatuses or a pair of the CMP apparatuses as a polishing section. In this case, polishing of two interconnect substrates can be carried out in parallel by alternately transporting the substrates, enabling considerable shortening of the overall polishing time.

### Example 1

Pretreatment solution 1 was prepared by dissolving 5-methyl benzotriazole as a corrosion inhibitor in ethanol as an organic solvent, with the amount of the benzothiazole being about 5 wt % of the amount of ethanol.

An interconnect wafer substrate with an interconnect metal (copper) embedded in interconnect recesses, covered with a barrier metal layer (such as tantalum, tantalum nitride, titanium, titanium nitride or ruthenium), such as to provide a 8-inch (20.3 cm) copper plating pattern, was provided. While rotating the interconnect substrate, with a processing surface (interconnect metal layer) facing upwardly, at a speed of about 1,000 to 5,000 rpm by a spin coater, the pretreatment solution 1 was dropped in an amount of 10 to 50 ml from above the center of the interconnect substrate, thereby applying the pretreatment solution 1 to the surface of the interconnect metal layer of the interconnect substrate. Thereafter, the interconnect substrate with the pretreatment solution 1 attached was subjected to CMP to polish away the extra interconnect metal layer and the exposed barrier metal layer and flatten the interconnect substrate surface. As a control test, the same interconnect wafer substrate was subjected to conventional CMP (not using the pretreatment solution 1). The surface configuration of each interconnect substrate after CMP was measured with a sensing pin-type profiler. As a result, the CMP with the use of the pretreatment solution 1 was found to produce a better effect of eliminating surface irregularities of the substrate.

What is claimed is:

1. A pre-polishing treatment solution for an interconnect substrate having an interconnect metal layer, comprising a corrosion inhibitor dissolved in an organic solvent.

2. The pretreatment solution according to claim 1, wherein the corrosion inhibitor is at least one member selected from the group consisting of 2,3-benzopyrrole, 2-ethyl imidazole, 4-methyl imidazole, 4-methyl-5-hydroxymethyl imidazole, 1-butyl-5-methyl imidazole, 1-phenyl-4-methyl imidazole, 1-(p-tolyl)-4-methyl imidazole, benzimidazole, 2-methyl benzimidazole, 5,6-dimethyl benzimidazole, 2-mercapto benzimidazole, 2-amino benzimidazole, benzotriazole, 5-methyl-1H-benzotriazole, 1-hydroxy benzotriazole, 4-hydroxy benzotriazole, 5-chloro benzotriazole, benzotriazole-5-carboxylic acid, 5-nitro benzotriazole, 1,2,4-triazole, 3-amino-1,2,4-triazole, 3-amino-5-methyl-4H-1,2,4-triazole, 3-phenyl-1,2,4-triazole-5-thione, 2-amino-4,6-dimethyl pyrimidine, 5-amino-1H-tetrazole, polyoxyethylene alkyl ether phosphate, polyoxyethylene phenyl ether phosphate, polyoxyethylene alkylphenyl ether phosphate, alkali metal salts or ammonium salts of these phosphate esters, oleic diethanolamide, linoleic diethanolamide, stearic diethanolamide, myristic diethanolamide, lauric diethanolamide, coconut fatty acid monoethanolamide and palm kernel fatty acid diethanolamide.

3. The pretreatment solution according to claim 1, wherein the concentration of the corrosion inhibitor in the organic solvent is 0.01 to 50% by weight.

4. The pretreatment solution according to claim 1, wherein the organic solvent is selected from methanol, ethanol, propanol, butanol, acetone, hexane and tetrahydrofuran.

5. A method for polishing an interconnect substrate, comprising:
the step of providing an interconnect substrate having an interconnect metal layer on a barrier metal layer;
the pretreatment solution application step of applying the pretreatment solution according to claim 1 to the interconnect substrate;
the first polishing step of flattening the interconnect metal layer; and
the second polishing step of removing the barrier metal layer exposed on the surface of the interconnect substrate.

6. The method according to claim 5, wherein the pretreatment solution application step is carried out as pretreatment before the first polishing step.

7. The method according to claim 5, wherein the pretreatment solution application step is carried out as pretreatment before the second polishing step.

8. The method according to claim 5, wherein the pretreatment solution application step is carried out as pretreatment before the first polishing step and as pretreatment before the second polishing step.

9. The method according to claim 5, wherein in the first polishing step and/or the second polishing step is carried out polishing selected from chemical mechanical polishing (CMP), electrolytic polishing and composite electrolytic polishing.

10. A polishing apparatus for an interconnect substrate, comprising:
a polishing section for polishing an interconnect substrate;
a pretreatment section for applying the pretreatment solution according to claim 1 to the interconnect substrate; and
a transport means for transporting the interconnect substrate between the pretreatment section and the polishing section.
